(19) United States
(12) Patent Application Publication
(10) Pub. No.: US 2022/0035246 A1
(43) Pub. Date: Feb. 3, 2022

(54) METHOD FOR PRODUCING PLATED FORMED PRODUCT

(71) Applicant: JSR CORPORATION, Tokyo (JP)

(72) Inventors: Naoki NISHIGUCHI, Minato-ku, Tokyo (JP); Tomoyuki MATSUMOTO, Minato-ku, Tokyo (JP); Akira ISHII, Minato-ku, Tokyo (JP); Ayako ENDO, Minato-ku, Tokyo (JP)

(73) Assignee: JSR CORPORATION, Tokyo (JP)

(21) Appl. No.: 17/298,769

(22) PCT Filed: Dec. 6, 2019
(86) PCT No.: PCT/JP2019/047828

§ 371 Date: Jun. 1, 2021

(30) Foreign Application Priority Data
Dec. 12, 2018 (JP) 2018-232869

(51) Int. Cl. G03F 7/039; H01L 21/027; H01L 21/3105; H01L 21/02; H01L 21/288; G03F 7/40; C25D 5/02

(52) U.S. Cl. CPC G03F 7/039; H01L 21/0274; H01L 21/31058; C25D 5/022; H01L 21/2885; G03F 7/40; H01L 21/02057

(57) ABSTRACT

A method for producing a plated formed product includes: a step (1) of forming on a substrate of the substrate having a metal film a resin film of a photosensitive resin composition containing a sulfur-containing compound having at least one selected from a mercapto group, a sulfide bond, and a polysulfide bond; a step (2) of exposing the resin film; a step (3) of developing the exposed resin film to form a resist pattern film; a step (4) of performing plasma treatment of a substrate having the resist pattern film on the metal film with oxygen-containing gas; and a step (5) of performing, after the plasma treatment, plating treatment with the resist pattern film as a mold.

### TECHNICAL FIELD

The present invention relates to a method for producing a plated formed product.

### BACKGROUND ART

To improve the performance of mobile devices such as smartphones and tablet terminals, semiconductor chips with different functions are packaged by using high-density packaging technology such as FO-WLP (Fan-Out Wafer Level Package), FO-PLP (Fan-Out Panel Level Package), TSV (Through Silicon Via), and silicon interposers.

In such packaging technology, the wiring and bumps used for electrical connections between semiconductor chips also becomes denser. Therefore, the resist pattern film used for forming wiring and bumps is also required to be fine and dense.

Wiring and bumps are typically plated formed products, and are produced by applying a photosensitive resin composition onto a substrate having a metal film such as a copper film to form a resist coating, exposing and developing the resist coating with a mask to form a resist pattern film, and plating the surface of the substrate with the resist pattern film as a mold (refer to Patent Literatures 1 and 2).

Thus, since the resist pattern film is formed on the metal film and then the plating treatment is performed, the photosensitive resin composition is required to have, for example, the adhesiveness between the resist pattern film and the metal film, and the rectangularity of the resist pattern shape that affects the shape of the plated formed product. One of the factors that affect the adhesiveness of the plated formed product is the skirt shape (also called footing) of the interface between the metal film and the resist pattern film. Particularly, a photosensitive resin composition containing a compound having a mercapto group or a sulfide bond is known in order to improve adhesiveness (refer to Patent Literature 3).

### CITATION LIST

### Patent Literature

Patent Literature 1: JP 2010-008972 A
Patent Literature 2: JP 2006-330368 A
Patent Literature 3: JP 2016-502142 A

### SUMMARY OF INVENTION

### Technical Problem

The investigation by the present inventors has found that when a resist pattern film is formed by using a photosensitive resin composition containing a compound having a mercapto group as in Patent Literature 3 and the plating treatment is performed by using the resist pattern film as a mold, the plated formed product can not be satisfactorily produced, for example, the plated formed product formed is easily peeled off. An object of the present invention is to provide a method for producing a plated formed product to allow the plated formed product to be satisfactorily produced.

### Solution to Problem

The present inventors have investigated to solve the above problems. As a result, it has been found that the above problems can be solved by a method for producing a plated formed product having the following steps, and the present invention has been completed. That is, the present invention relates to, for example, the following [1] to [8].

[1] A method for producing a plated formed product, the method including: a step (1) of forming on a substrate of the substrate having a metal film a resin film of a photosensitive resin composition containing a sulfur-containing compound having at least one selected from a mercapto group, a sulfide bond, and a polysulfide bond; a step (2) of exposing the resin film; a step (3) of developing the exposed resin film to form a resist pattern film; a step (4) of performing plasma treatment of a substrate having the resist pattern film on the metal film with oxygen-containing gas; and a step (5) of performing, after the plasma treatment, plating treatment with the resist pattern film as a mold.

[2] The method for producing a plated formed product according to the above [1], wherein the photosensitive resin composition further contains polymer (A) having an acid dissociative group and photoacid generator (B).

[3] The method for producing a plated formed product according to the above [2], wherein a content of the sulfur-containing compound is 0.2 to 2.0 parts by mass, with respect to 100 parts by mass of a polymer component including polymer (A) having an acid dissociative group included in the photosensitive resin composition.

[4] The method for producing a plated formed product according to any one of [1] to [3], wherein the resist pattern film has a thickness of 1 to 100 μm.

[5] The method for producing a plated formed product according to any one of [1] to [4], wherein the metal film is a copper film.

[6] The method for producing a plated formed product according to any one of [1] to [5], wherein the plating treatment is a copper plating treatment.

[7] The method for producing a plated formed product according to any one of [1] to [6], including a step of washing a substrate having a plasma-treated resist pattern film on a metal film with an acid before the step (5).

[8] The method for producing a plated formed product according to any one of [1] to [6], including a step of washing a substrate having a plasma-treated resist pattern film on a metal film with an aqueous solution of potassium permanganate or an aqueous solution of sulfuric acid before the step (5).

### Advantageous Effects of Invention

The present invention can provide a method for producing a plated formed product to allow the plated formed product to be satisfactorily produced.

### BRIEF DESCRIPTION OF DRAWING

FIG. 1 is a diagram illustrating a footing.

### DESCRIPTION OF EMBODIMENTS

Hereinafter, modes for carrying out the present invention will be described.

### [Method for Producing Plated Formed Product]

A method for producing a plated formed product includes:

a step (1) of forming on the metal film of a substrate having a metal film a resin film of a photosensitive resin composition containing a sulfur-containing compound (hereinafter also referred to as “compound (C)”) having at least one selected from a mercapto group, a sulfide bond, and a polysulfide bond;

a step (2) of exposing the resin film;

a step (3) of developing the exposed resin film to form a resist pattern film;

a step (4) of performing plasma treatment of a substrate having the resist pattern film on the metal film with oxygen-containing gas; and

a step (5) of performing, after the plasma treatment, plating treatment with the resist pattern film as a mold.

The method for producing a plated formed product according to the present invention can form a resist pattern film having high adhesiveness to a metal film, and can satisfactorily produce the plated formed product with this resist pattern film as a mold.

The reason why the present invention exhibits the above effects is presumed as follows.

Containing compound (C) in the photosensitive resin composition can improve the adhesiveness between the resist pattern film formed from the photosensitive resin composition and the metal film. It is considered that the mercapto group, sulfide bond, or polysulfide bond included in compound (C) contributes to the improvement of the adhesiveness of the resist pattern film to the metal film.

Plasma-treating the substrate having the resist pattern film on the metal film with oxygen-containing gas can produce the plated formed product that is hardly peeled off from the metal film and has a good shape. In the above production method, it is considered that after the above development, compound (C)-containing film that has not been removed by development is formed on the surface of the metal film at the opening of the resist pattern film. Sulfur atoms included in compound (C) can cause uneven plating and corrosion. Therefore, the plating treatment can be satisfactorily performed by removing compound (C)-containing film on the surface of the metal film at the opening of the resist pattern film by plasma treatment after the formation of the resist pattern film and before the plating treatment, and thus by enhancing the affinity between the surface of the metal film and a plating solution.

The above description is speculative and does not limit the present invention.

### [Step (1)]

In the step (1), a resin film of the photosensitive resin composition containing compound (C) is formed on the metal film of the substrate having the metal film.

Examples of the substrate include a semiconductor substrate and a glass substrate. The shape of the substrate is not particularly limited, and the surface shape includes a flat plate shape and an uneven shape, and the shape of the substrate includes a circular shape and a square shape. In addition, there is no limit to the size of the substrate.

Examples of the metal film include a film containing a metal such as aluminum, copper, silver, gold, and palladium, and a film containing two or more alloys containing the metal, and a copper film, that is, the film including copper and/or copper alloy is preferable. The thickness of the metal film is typically 100 to 10000 Å, and preferably 500 to 2000 Å. The metal film is typically provided on the surface of the substrate. The metal film can be formed by a method such as a sputtering method.

The resin film is typically formed by applying the photosensitive resin composition onto the metal film of a substrate having a metal film. Examples of the coating method of the above composition include a spin coating method, a roll coating method, a screen printing method, and an applicator method, and of these, the spin coating method and the screen printing method are preferable.

The photosensitive resin composition is applied, and then this composition applied can be heat-treated for the purpose of, for example, volatilizing an organic solvent. The conditions for the heat treatment are typically 0.5 to 20 minutes at 50 to 200° C.

The thickness of the resin film is typically 1 to 100 μm, and preferably 5 to 80 μm.

Hereinafter, the photosensitive resin composition used in the step (1) will be described. The photosensitive resin composition contains compound (C) having at least one selected from a mercapto group, a sulfide bond, and a polysulfide bond.

In the present description, the polysulfide bond means a bond formed between two or more sulfur atoms, and examples thereof include a disulfide bond (—S—S—) and a trisulfide bond (—S—S—S—). The number of sulfur atoms in the polysulfide bond is typically 2 or more, and preferably 2 to 3.

Details of compound (C) are described in the <Compound (C)> column.

A conventionally known photosensitive resin composition can be used as long as the above photosensitive resin composition contains compound (C). In addition, the photosensitive resin composition may be either a positive type or a negative type, a positive type photosensitive resin composition is preferable, and a positive type chemically amplified photosensitive resin composition is more preferable.

Examples of the negative type photosensitive resin composition include an alkali-soluble resin, a photopolymerizable unsaturated double bond-containing compound (for example, (meth)acrylic compound), a photoradical polymerization initiator, and a compound (C)-containing resin composition. Examples of the negative type photosensitive resin composition containing an alkali-soluble resin, a photopolymerizable unsaturated double bond-containing compound, and a photoradical polymerization initiator include resin compositions described in JP 2015-143813 A, JP 2015-043060 A, and International Publication No. 2013/084886, and for example, compound (C) may be added to this resin composition. The resin composition described in the above publication shall be described in the present description.

Examples of the positive type chemically amplified photosensitive resin composition (hereinafter, also referred to as “positive type composition”) include the resin composition containing polymer (A) having an acid dissociative group (hereinafter, also referred to as “polymer (A)”), a photoacid generator (B), and compound (C). Hereinafter, each component will be described.

Unless otherwise specified, each component exemplified in the present description, for example, each component in the photosensitive resin composition and each structural unit in polymer (A), may be included singly, or two or more thereof may be included.

### <Compound (C)>

Compound (C) has at least one selected from a mercapto group, a sulfide bond, and a polysulfide bond. In one embodiment, when photoacid generator (B) having these groups or bonds is used, compound (C) other than this photoacid generator can be selected and used.

The total number of mercapto groups, sulfide bonds, and polysulfide bonds in compound (C) is not particularly limited, and is typically 1 to 10, preferably 1 to 6, and more preferably 2 to 4.

Examples of compound (C) include compound (C1) represented by formula (C1), compound (C2) represented by formula (C2), the multimer of the compound (C2), and compound (C3) represented by formula (C3), which will be described below. The compound (C1) and the compound (C2) are preferable, and the compound (C2) is more preferable, because peeling of the resist pattern film from the substrate during the plating treatment can be suppressed.

Compound (C) tends to be highly hydrophobic in one embodiment. The partition coefficient is an index for the hydrophobicity of compound (C). The partition coefficient of compound (C) is preferably 2 to 10, and more preferably 3 to 7. The partition coefficient is the value of the octanol/water partition coefficient (log P) calculated by the C log P method, and the value is larger, meaning that the hydrophobicity (fat solubility) is higher.

The positive type composition can contain one or more compounds (C).

The lower limit of the content of compound (C) in the positive type composition is typically 0.01 parts by mass, preferably 0.05 parts by mass, more preferably 0.1 parts by mass, and particularly preferably 0.2 parts by mass with respect to 100 parts by mass of the polymer component containing polymer (A), and the upper limit of the content is typically 10 parts by mass, preferably 3.0 parts by mass, more preferably 2.0 parts by mass, and particularly preferably 1.0 part by mass. In such an aspect, the positive type composition can more exhibit the above effect. For example, when the content of compound (C) is 0.2 parts by mass or more, a resist pattern film having a higher rectangularity tends to be able to be formed. In addition, for example, when the content of compound (C) is 2.0 parts by mass or less, the adhesion of the plated formed product to the substrate having the metal film tends to be higher.

### «Compound (C1)»

Compound (C1) is a compound represented by formula (C1).

### [Chemical Formula 1]

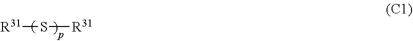

In formula (C1), R³¹ is each independently a monovalent hydrocarbon group or a group obtained by substituting at least one hydrogen atom in the monovalent hydrocarbon group with a mercapto group (hereinafter, also referred to as “mercapto substituent”). p is an integer of 1 or more, preferably an integer of 1 to 4, and more preferably an integer of 2 to 3. For example, when p is 3, compound (C1) has a trisulfide bond. When p is 1, at least one R³¹ is preferably a group obtained by substituting at least one hydrogen atom in the monovalent hydrocarbon group with a mercapto group.

The monovalent hydrocarbon group of R³¹ is typically a monovalent hydrocarbon group having 1 to 12 carbon atoms. Examples of the monovalent hydrocarbon group include an alkyl group, an aryl group, and an arylalkyl group.

Examples of the alkyl group of R³¹ include an alkyl group having 1 to 10 carbon atoms such as a methyl group, an ethyl group, an n-propyl group, an isopropyl group, a pentyl group, and a decyl group.

Examples of the aryl group of R³¹ include an aryl group having 6 to 10 carbon atoms such as a phenyl group, a methylphenyl group, and a naphthyl group.

Examples of the arylalkyl group of R³¹ include an arylalkyl group having 7 to 12 carbon atoms such as a benzyl group and a phenethyl group.

Examples of the mercapto substituent include a 4-mercaptophenyl group.

In compound (C1), a sulfide bond (when p=1), a polysulfide bond (when p is an integer of 2 or more) or a mercapto group (when R³¹ is a mercapto substituent) is bonded to the hydrocarbon structure. Therefore, it is presumed that compound (C1) has high hydrophobicity.

Examples of compound (C1) include compounds represented by the following formulas (C1-1) to (C1-3).

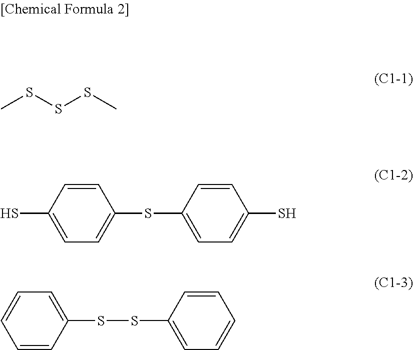

### «Compound (C2) and its Multimer»

Compound (C2) is a compound represented by formula (C2).

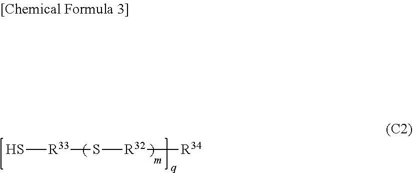

The meaning of each symbol in formula (C2) is as follows.

R³² is a divalent hydrocarbon group, preferably an alkanediyl group, an arylene group, or an arylene alkanediyl group, and of these, an alkanediyl group is more preferable because a plated formed product can be satisfactorily produced.

R³³ is a divalent hydrocarbon group or a group obtained by substituting at least one —CH₂— group (excluding both ends) in the divalent hydrocarbon group with —S— or —O—, preferably an alkanediyl group, a group obtained by substituting at least one —CH₂— group (excluding both ends) in the alkanediyl group with —S— or —O— (hereinafter, also referred to as “substituted alkanediyl group”), an allylene group, or an allylene alkanediyl group, and of these, the alkanediyl group is more preferable because a plated formed product can be satisfactorily produced.

The alkanediyl group typically has 1 to 12 carbon atoms, and preferably 2 to 12 carbon atoms. Examples of the alkanediyl group include: a linear alkanediyl group such as a methylene group, an ethylene group, a propane-1,3-diyl group, a butane-1,4-diyl group, a pentane-1,5-diyl group, a hexane-1,6-diyl group, an octane-1,8-diyl group, a decane-1,10-diyl group, and a dodecane-1,12-diyl group; and a branched alkanediyl group such as 1-methylpropane-1,3-diyl group, 2-methylpropane-1,3-diyl group, 1-methylbutane-1,4-diyl group, and 2-methylbutane-1,4-diyl group. Of these, a linear alkanediyl group is preferable.

Examples of the substituted alkanediyl group include a group represented by —CH₂—CH₂—S—CH₂—CH₂— and a group represented by —CH₂—CH₂—O—CH₂—CH₂—O—CH₂—CH₂—.

Examples of the arylene group include an arylene group having 6 to 10 carbon atoms such as a phenylene group, a methylphenylene group, and a naphthylene group.

The arylene alkanediyl group is a divalent group obtained by bonding one or more arylene groups with one or more alkanediyl groups in an arbitrary order. Examples of each of arylene group and alkanediyl group include the above specific examples.

R³⁴ represents a glycoluril ring structure or an isocyanul ring structure. Although the glycoluril ring structure and the isocyanul ring structure have a bond that can reduce the hydrophobicity, it is presumed that the hydrophobicity of compound (C2) is not deteriorated because of the high structural symmetry thereof.

m is 1 or 0.

q is an integer of 1 to 4. When R³¹ is a glycoluril ring structure, q is an integer of 1 to 4. When R³⁴ is an isocyanul ring structure, q is an integer of 1 to 3. When q is an integer of 2 or more, the group represented by —((R³²—S)ₘ—R³³—SH in formula (C2) may be the same or different.

In compound (C2), the mercapto group or sulfide bond (when m is 1) is bonded to a hydrocarbon structure or a structure having —S— or —O— in a part of the hydrocarbon structure. Therefore, it is presumed that compound (C2) has high hydrophobicity.

Compound (C2-1) represented by formula (C2-1) and compound (C2-2) represented by formula (C2-2) are preferable, and compound (C2-1) is more preferable, as compound (C2).

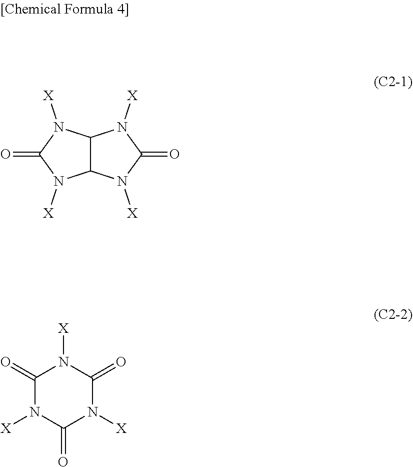

In formulas (C2-1) and (C2-2), X each independently represents a hydrogen atom or a monovalent group represented by formula (g2). However, in formula (C2-1), at least one X is a monovalent group represented by formula (g2), and preferably all of X are monovalent groups represented by formula (g2). In addition, in formula (C2-2), at least one X is a monovalent group represented by formula (g2), and preferably all of X are monovalent groups represented by formula (g2).

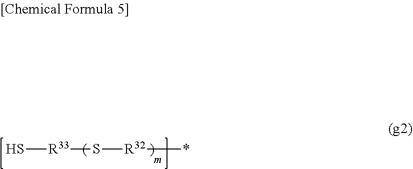

In formula (g2), R³², R³³, and m are synonymous with R³², R³³, and m, respectively, and * is a bonding hand with a nitrogen atom in formula (C2-1) or formula (C2-2).

Examples of the compound (C2-1) include 1,3,4,6-tetrakis[2-mercaptoethyl]glycoluril, 1,3,4,6-tetrakis[3-(2-mercaptoethylsulfanyl)propyl]glycoluril, 1,3,4,6-tetrakis[3-(3-mercaptopropylsulfanyl)propyl]glycoluril, 1,3,4,6-tetrakis[3-(4-mercaptobutylsulfanyl)propyl]glycoluril, 1,3,4,6-tetrakis [3-(5-mercaptopentylsulfanyl)propyl]glycoluril, 1,3,4,6-tetrakis[3-(6-mercaptohexylsulfanyl)propyl]glycoluril, 1,3,4,6-tetrakis[3-(8-mercaptooctylsulfanyl)propyl]glycoluril, 1,3,4,6-tetrakis[3-(10-mercaptodecylsulfanyl)propyl]glycoluril, 1,3,4,6-tetrakis[3-(12-mercaptododecylsulfanyl)propyl]glycoluril, 1,3,4,6-tetrakis[3-[2-(2-mercaptoethylsulfanyl)ethylsulfanyl]propyl]glycoluril, and 1,3,4,6-tetrakis (3-[2-[2-(2-mercaptoethoxy)ethoxy]ethylsulfanyl]propyl)glycoluril.

Examples of the compound (C2-2) include 1,3,5-tris[2-mercaptoethyl]isocyanurate, 1,3,5-tris[3-(2-mercaptoethylsulfanyl)propyl]isocyanurate, 1,3,5-tris[3-(3-mercaptopropylsulfanyl)propyl]isocyanurate, 1,3,5-tris[3-(4-mercaptobutylsulfanyl)propyl]isocyanurate, 1,3,5-tris[3-(5-mercaptopentylsulfanyl)propyl]isocyanurate, 1,3,5-tris[3-(6-mercaptohexylsulfanyl)propyl]isocyanurate, 1,3,5-tris[3-(8-mercaptooctylsulfanyl)propyl]isocyanurate, 1,3,5-tris[3-(10-mercaptodecylsulfanyl)propyl]isocyanurate, 1,3,5-tris[3-(12-mercaptododecylsulfanyl)propyl]isocyanurate, 1,3,5-tris[3-[2-(2-mercaptoethylsulfanyl)ethylsulfanyl]propyl]isocyanurate, and 1,3,5-tris(3-[2-[2-(2-mercaptoethoxy)ethoxy]ethylsulfanyl]propyl)isocyanurate.

Compound (C2) can be synthesized, for example, by the methods described in JP 2016-169174 A, JP 2016-164135 A, and JP 2016-164134 A.

Compound (C2) may form a multimer. The above multimer is a multimer obtained by forming a disulfide bond by coupling a plurality of compounds (C2) with a mercapto group. The multimer is, for example, a dimer to a pentamer of compound (C2).

### «Compound (C3)»

Compound (C3) is a compound represented by formula (C3).

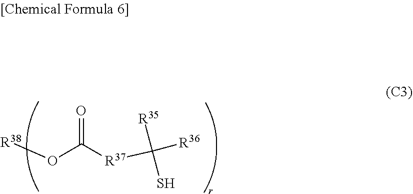

In formula (C3), R³⁵ and R³⁶ each independently represent a hydrogen atom or an alkyl group. R³⁷ is a single bond or an alkanediyl group. R³⁸ is an r-valent aliphatic group that may contain an atom other than a carbon atom. r is an integer of 2 to 10.

Examples of the alkyl group of R³⁵ and R³⁶ include an alkyl group having 1 to 10 carbon atoms, preferably 1 to 4 carbon atoms such as a methyl group, an ethyl group, a n-propyl group, an isopropyl group, a pentyl group, and a decyl group. As R³⁵ and R³⁶, a combination in which one is a hydrogen atom and the other is an alkyl group is preferable.

The alkanediyl group of R³⁷ typically has 1 to 10 carbon atoms, and preferably 1 to 5 carbon atoms. Examples of the alkanediyl group include: a linear alkanediyl group such as a methylene group, an ethylene group, a propane-1,3-diyl group, a butane-1,4-diyl group, a pentane-1,5-diyl group, and a decane-1,10-diyl group; and a branched alkanediyl group such as 1-methylpropane-1,3-diyl group, 2-methylpropane-1,3-diyl group, 1-methylbutane-1,4-diyl group, and 2-methylbutane-1,4-diyl group. Of these, a linear alkanediyl group is preferable.

R³⁸ is an r-valent (2 to 10-valent) aliphatic group that may contain an atom other than a carbon atom. Examples of the atom other than a carbon atom include a nitrogen atom, an oxygen atom, a sulfur atom, a fluorine atom, a chlorine atom, a bromine atom, and an iodine atom. The structure of the above aliphatic group may be linear, branched, or cyclic, or may be a combination of these structures.

Examples of the aliphatic group include an r-valent hydrocarbon group having 2 to 10 carbon atoms, an oxygen-containing r-valent aliphatic group having 2 to 10 carbon atoms, and a trivalent group having an isocyanul ring structure and 6 to 10 carbon atoms.

Examples of the compound (C3) include the compounds represented by the following formulas (C3-1) to (C3-4).

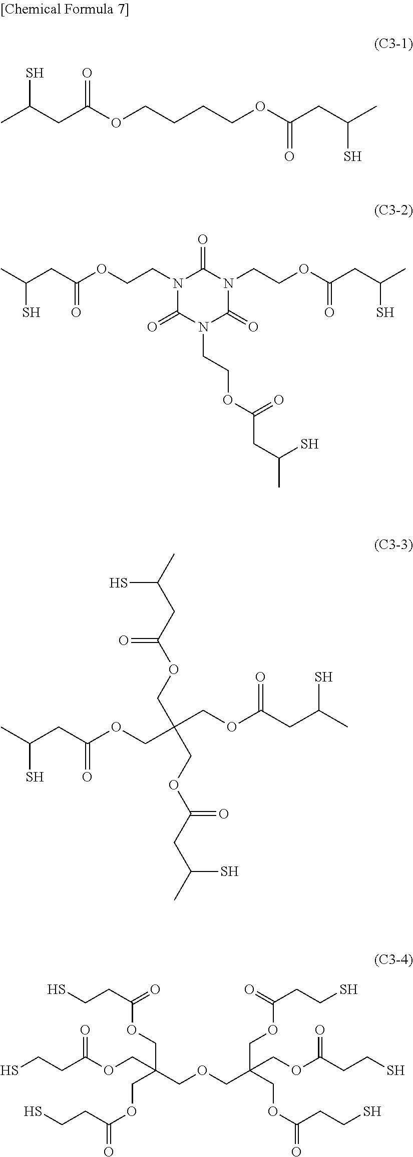

### <Polymer (A)>

Polymer (A) has an acid dissociative group.

The acid dissociative group is a group that can be dissociated by the action of an acid generated from photoacid generator (B). As a result of the dissociation, acidic functional groups such as a carboxy group and a phenolic hydroxyl group are generated in polymer (A). As a result, the solubility of polymer (A) in the alkaline developer changes, and the positive type composition can form a resist pattern film.

Polymer (A) has an acidic functional group protected by an acid dissociative group. Examples of the acidic functional group include a carboxy group and a phenolic hydroxyl group. Examples of polymer (A) include a (meth)acrylic resin in which a carboxy group is protected by an acid dissociative group, and a polyhydroxystyrene resin in which a phenolic hydroxyl group is protected by an acid dissociative group.

The polystyrene-equivalent weight average molecular weight (Mw) of polymer (A) measured by gel permeation chromatography is typically 1000 to 500000, preferably 3000 to 300000, more preferably 10000 to 100000, and still more preferably 20000 to 60000.

The ratio of Mw of polymer (A) to the polystyrene-equivalent number average molecular weight (Mn) measured by gel permeation chromatography, (Mw/Mn), is typically 1 to 5, and preferably 1 to 3.

The positive type composition can contain one or more polymers (A).

The content ratio of polymer (A) in the positive type composition is typically 70 to 99.5% by mass, preferably 80 to 99% by mass, and more preferably 90 to 98% by mass, with respect to 100% by mass of the solid content of the composition. The above solid content refers to all components other than the organic solvent described later.

«Structural Unit (a1)»

Polymer (A) typically has structural unit (a1) having an acid dissociative group.

Examples of structural unit (a1) include the structural unit represented by formula (a1-10) and the structural unit represented by formula (a1-20), and the structural unit represented by formula (a1-10) is preferable.

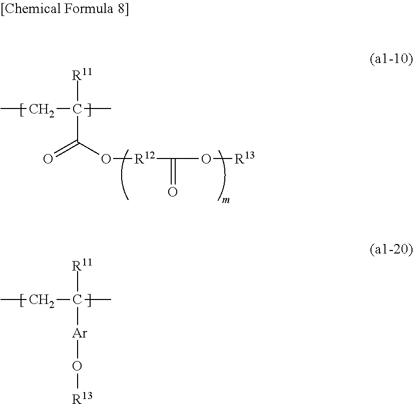

The meanings of the symbols in formulas (a1-10) and (a1-20) are as follows.

R¹¹ is a hydrogen atom, an alkyl group having 1 to 10 carbon atoms, or a group obtained by substituting at least one hydrogen atom in the alkyl group (hereinafter also referred to as “substituted alkyl group”) with another group such as a halogen atom including a fluorine atom and a bromine atom, an aryl group including a phenyl group, a hydroxyl group, and an alkoxy group.

R¹² is a divalent organic group having 1 to 10 carbon atoms.

Ar is an arylene group having 6 to 10 carbon atoms.

R¹³ is an acid dissociative group.

m is an integer of 0 to 10, preferably an integer of 0 to 5, and more preferably an integer of 0 to 3.

Examples of the alkyl group having 1 to 10 carbon atoms include a methyl group, an ethyl group, an n-propyl group, an isopropyl group, an n-butyl group, a pentyl group, and a decyl group.

Examples of the divalent organic group having 1 to 10 carbon atoms include: an alkanediyl group having 1 to 10 carbon atoms such as a methylene group, an ethylene group, a propane-1,3-diyl group, a propane-1,2-diyl group, and a decane-1,10-diyl group; and a group obtained by substituting at least one hydrogen atom in the alkanediyl group with another group such as a halogen atom including a fluorine atom and a bromine atom, an aryl group including a phenyl group, a hydroxyl group, and an alkoxy group.

Examples of the arylene group having 6 to 10 carbon atoms include a phenylene group, a methylphenylene group, and a naphthylene group.

Examples of the acid dissociative group include a group that dissociates due to the action of an acid and thereby generates an acidic functional group such as a carboxy group and a phenolic hydroxyl group in polymer (A). Specific examples thereof include an acid dissociative group represented by formula (g1) and a benzyl group, and the acid dissociative group represented by formula (g1) is preferable.

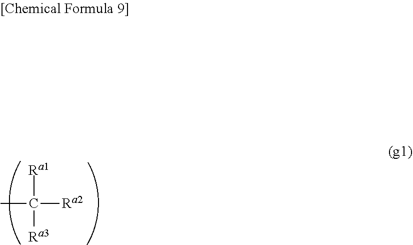

In the formula (g1), R^{a1} to R^{a3} each independently represent an alkyl group, an alicyclic hydrocarbon group, or a group obtained by substituting at least one hydrogen atom in the alkyl group or the alicyclic hydrocarbon group with another group such as a halogen atom including a fluorine atom and a bromine atom, an aryl group including a phenyl group, a hydroxyl group, and an alkoxy group. R^{a1} and R^{a2} may be bonded to each other to form an alicyclic structure together with the carbon atom C to which R^{a1} and R^{a2} are bonded.

Examples of the alkyl group of R^{a1} to R^{a3} include an alkyl group having 1 to 10 carbon atoms such as a methyl group, an ethyl group, an n-propyl group, an isopropyl group, an n-butyl group, a pentyl group, and a decyl group.

Examples of the alicyclic hydrocarbon group of R^{a1} to R^{a3} include: a monocyclic saturated cyclic hydrocarbon groups such as a cyclobutyl group, a cyclopentyl group, a cyclohexyl group, a cycloheptyl group, and a cyclooctyl group; a monocyclic unsaturated cyclic hydrocarbon group such as a cyclobutenyl group, a cyclopentenyl group, and a cyclohexenyl group; and a polycyclic saturated cyclic hydrocarbon group such as a norbornyl group, an adamantyl group, a tricyclodecyl group, and a tetracyclododecyl group.

Examples of the alicyclic structure formed by R^{a1}, R^{a2}, and carbon atom C includes: a monocyclic saturated cyclic hydrocarbon structure such as cyclobutyl, cyclopentyl, cyclohexyl, cycloheptyl, and cyclooctyl; a monocyclic unsaturated cyclic hydrocarbon structure such as cyclobutenyl, cyclopentenyl, and cyclohexenyl; and a polycyclic saturated cyclic hydrocarbon structure such as norbornyl, adamantyl, tricyclodecyl, and tetracyclododecyl.

The groups represented by formulas (g11) to (g15) are preferable as the acid dissociative group represented by formula (g1).

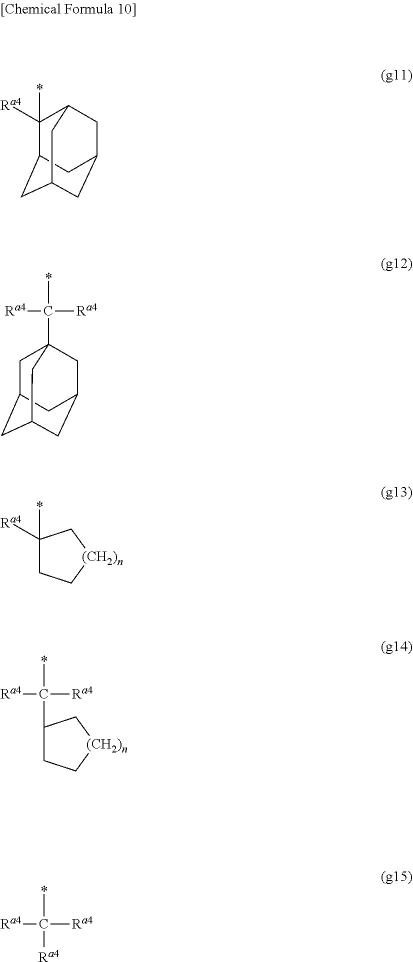

In formulas (g11) to (g15), R^{a4} each independently represents an alkyl group having 1 to 10 carbon atoms such as a methyl group, an ethyl group, an isopropyl group, and an n-butyl group, and n is an integer of 1 to 4. Each ring structure in formulas (g11) to (g14) may have one or more substituents such as an alkyl group having 1 to 10 carbon atoms, a halogen atom such as a fluorine atom and a bromine atom, a hydroxyl group, and an alkoxy group. * indicates a bonding hand.

In addition to the structural units shown in formulas (a1-10) and (a1-20), examples of structural unit (a1) include: a structural unit having an acetal-based acid dissociative group described in JP 2005-208366 A, JP 2000-194127 A, JP 2000-267283 A, and JP 2004-348106 A; a structural unit having a sultone ring described in JP 2013-101321 A; and a structural unit having a crosslinked acid dissociative group described in JP 2000-214587 A and JP 2000-199960 Å.

The structural units described in the above publication shall be described in the present description.

Polymer (A) can have one or more structural units (a1).

The content ratio of structural unit (a1) in polymer (A) is typically 10 to 50 mol %, preferably 15 to 45 mol %, and more preferably 20 to 40 mol %.

In the present description, the content ratio of each structural unit in polymer (A) is a value when the total of all the structural units constituting polymer (A) is 100 mol %. Each of the structural units is typically derived from a monomer in the synthesis of polymer (A). The content ratio of each structural unit can be measured by ¹H-NMR.

«Structural Unit (a2)»

Polymer (A) can further have structural unit (a2) having a group that promotes solubility in an alkaline developer (hereinafter, also referred to as “solubility promoting group”). Polymer (A) having structural unit (a2) can adjust lithographic characteristics such as the resolution, sensitivity, and depth of focus of the resin film formed from the positive type composition.

Examples of structural unit (a2) include a structural unit having at least one group or structure selected from a phenolic hydroxyl group, a carboxy group, an alcoholic hydroxyl group, a lactone structure, a cyclic carbonate structure, a sultone structure, and a fluoroalcohol structure (those corresponding to structural unit (a1) are excluded). Of these, a structural unit having a phenolic hydroxyl group is preferable because of being capable of forming a resist pattern film that is resistant to pressing from plating when forming a plated formed product.

Examples of the structural unit having a phenolic hydroxyl group include a structural unit derived from the monomer having a hydroxyaryl group such as 2-hydroxystyrene, 4-hydroxystyrene, 4-isopropenylphenol, 4-hydroxy-1-vinylnaphthalene, 4-hydroxy-2-vinylnaphthalene, and 4-hydroxyphenyl(meth)acrylate. Examples of the hydroxyaryl group include: a hydroxyphenyl group such as a hydroxyphenyl group, a methylhydroxyphenyl group, a dimethylhydroxyphenyl group, a dichlorohydroxyphenyl group, a trihydroxyphenyl group, and a tetrahydroxyphenyl group; and a hydroxynaphthyl group such as a hydroxynaphthyl group and a dihydroxynaphthyl group.

Examples of the structural unit having a carboxy group include a structural unit derived from the monomer such as (meth)acrylic acid, crotonic acid, maleic acid, fumaric acid, cinnamic acid, 2-carboxyethyl(meth)acrylate, 2-carboxypropyl(meth)acrylate, and 3-carboxypropyl(meth)acrylate, and a structural unit described in JP 2002-341539 A.

Examples of the structural unit having an alcoholic hydroxyl group include a structural unit derived from the monomer such as 2-hydroxyethyl(meth)acrylate and 3-(meth)acryloyloxy-4-hydroxytetrahydrofuran, and a structural unit described in JP 2009-276607 A.

Polymer (A) can have one or more structural units (a2).

The content ratio of structural unit (a2) in polymer (A) is typically 10 to 80 mol %, preferably 20 to 65 mol %, and more preferably 25 to 60 mol %. As long as the content ratio of structural unit (a2) is within the above range, the dissolution rate in an alkaline developer can be increased, and as a result, the resolution of the positive type composition in a thick film can be improved.

Polymer (A) can have structural unit (a2) in the same polymer as or different polymer from the polymer having structural unit (a1); however, polymer (A) preferably has the structural units (a1) to (a2) in the same polymer.

«Structural Unit (a3)»

Polymer (A) can further have another structural unit (a3) other than structural units (a1) to (a2). Examples of the structural unit (a3) include a structural unit derived from a monomer including: an aliphatic (meth)acrylic acid ester compound including alkyl(meth)acrylate, alkoxyalkyl(meth)acrylate, and alkoxy(poly)alkyleneglycol(meth)acrylate; an alicyclic (meth)acrylic acid ester compound; an aromatic ring-containing (meth)acrylic acid ester compound; a styrene vinyl-based compound; an unsaturated nitrile compound; an unsaturated amide compound; and an unsaturated imide compound.

Polymer (A) can have one or more structural units (a3).

The content ratio of structural unit (a3) in polymer (A) is typically 40 mol % or less.

Polymer (A) can have structural unit (a3) in the same polymer as or different polymer from the polymer having structural unit (a1) and/or structural unit (a2); however, polymer (A) preferably has the structural units (a1) to (a3) in the same polymer.

### <Photoacid Generator (B)>

Photoacid generator (B) is a compound that generates an acid by exposure. The action of this acid makes dissociated the acid dissociative group in polymer (A) to generate an acidic functional group such as a carboxy group and a phenolic hydroxyl group. As a result, the exposed portion of the resin film formed from the positive type composition becomes easily soluble in an alkaline developer, and a positive resist pattern film can be formed.

Examples of photoacid generator (B) include the compounds described in JP 2004-317907 A, JP 2014-157252 A, JP 2002-268223 A, JP 2017-102260 A, JP 2016-018075 A, and JP 2016-210761 A. These shall be described herein. Specific examples of the photoacid generator (B) include an onium salt compound, a halogen-containing compound, a sulfon compound, a sulfonic acid compound, a sulfonimide compound, and a diazomethane compound.

The above positive type composition can contain one or more photoacid generators (B).

The content of photoacid generator (B) in the positive type composition is typically 0.1 to 20 parts by mass, preferably 0.3 to 15 parts by mass, and more preferably 0.5 to 10 parts by mass with respect to 100 parts by mass of polymer (A). When the content of photoacid generator (B) is within the above range, the resist pattern film having better resolution tends to be obtained.

### <Other Components>

The above positive type composition can further contain other components.

Examples of the other component include: a quencher that controls the diffusion of the acid generated by exposure from photoacid generator (B) in the resin film (for example, the compound represented by formula (D-1) or (D-2) described later); a surfactant that has the effect of improving the coatability, antifoaming properties of the positive type composition; a sensitizer that absorbs exposure light and improves the acid generation efficiency of the photoacid generator; an alkali-soluble resin or low molecular weight phenol compound that controls the dissolution rate of the resin film formed from the positive type composition in an alkaline developer; an ultraviolet absorber that blocks the light reaction caused by the scattered light wrapping around the unexposed area during exposure; a thermal polymerization inhibitor that enhances the storage stability of the positive type composition; and others including an antioxidant, an adhesive aid, and an inorganic filler. The polymer component described above can include an alkali-soluble resin in addition to polymer (A).

### <Organic Solvent>

The positive type composition can further contain an organic solvent. The organic solvent is, for example, a component used for uniformly mixing each component included in the positive type composition.

Examples of the organic solvent include an alcohol solvent, an ester solvent, a ketone solvent, an alkylene glycol dialkyl ether, and an alkylene glycol monoalkyl ether acetate.

The positive type composition can contain one or more organic solvents.

The content ratio of the organic solvent in the positive type composition is typically 40 to 90% by mass.

### <Production of Positive Type Composition>

The positive type composition can be produced by uniformly mixing each component described above. In addition, in order to remove impurities, each of the above components is uniformly mixed, and then the obtained mixture can be filtered with a filter.

### [Step (2)]

In the step (2), the resin film formed in the step (1) is exposed.

The exposure is typically performed on the resin film selectively by a unit magnification projection exposure or reduced projection exposure via a photomask having a predetermined mask pattern. Examples of the exposure light include ultraviolet rays or visible light having a wavelength of 150 to 600 nm, and preferably 200 to 500 nm. Examples of the light source of the exposure light include a low-pressure mercury lamp, a high-pressure mercury lamp, an ultra-high-pressure mercury lamp, a metal halide lamp, and a laser. The exposure amount can be appropriately selected depending on the type of exposure light, the type of the photosensitive resin composition, and the thickness of the resin film, and is typically 100 to 20,000 mJ/cm².

After the exposure to the resin film, the resin film can be heat-treated before development. The conditions for the heat treatment are typically 0.5 to 10 minutes at 70 to 180° C. When the positive type composition is used, the heat treatment can promote the dissociation reaction due to the acid of the acid dissociative group in polymer (A).

### [Step (3)]

In the step (3), the resin film exposed in the step (2) is developed to form a resist pattern film. Development is typically performed by using an alkaline developer. Examples of the developing method include a shower method, a spray method, a dipping method, a liquid filling method, and a paddle method. The developing conditions are typically 1 to 30 minutes at 10 to 30° C.

Examples of the alkaline developer include an aqueous solution containing one or more alkaline substances. Examples of the alkaline substance include sodium hydroxide, potassium hydroxide, sodium carbonate, sodium silicate, aqueous ammonia, ethylamine, n-propylamine, diethylamine, triethylamine, monoethanolamine, diethanolamine, triethanolamine, tetramethylammonium hydroxide, tetraethylammonium hydroxide, choline, pyrrole, and piperidine. The concentration of the alkaline substance in the alkaline developer is typically 0.1 to 10% by mass. The alkaline developer can further contain, for example, an organic solvent such as methanol or ethanol, and/or a surfactant.

The resist pattern film formed by development can be washed with water for example. Then, the above resist pattern film can be dried by using an air gun or a hot plate.

As described above, a resist pattern film serving as a mold for forming a plated formed product can be formed on the metal film of a substrate.

The thickness of the resist pattern film is typically 1 to 100 μm, and preferably 5 to 80 μm. The diameter of the opening (for example, in the case of the positive type, the portion removed by development) in the resist pattern film is typically 0.5 to 10000 μm, and preferably 0.8 to 1000 μm.

A shape suitable for the type of the plated formed product can be selected as the shape of the opening of the resist pattern film. When the plated formed product is a wiring, the shape of the pattern is, for example, a line-and-space pattern, and when the plated formed product is a bump, the shape of the opening is, for example, a cubic hole pattern.

### [Step (4)]

In the step (4), performing the plasma treatment with the oxygen-containing gas (surface treatment of the plating substrate) can enhance the affinity between the metal film surface and the plating solution. In the step (4), for example, the substrate having the resist pattern film on the metal film is placed in a vacuumed apparatus, oxygen plasma is emitted, and the surface treatment of the substrate is performed. The plasma treatment conditions are that the power supply output is typically 50 to 300 W, the flow rate of oxygen-containing gas is typically 20 to 150 mL, the pressure inside the apparatus is typically 10 to 30 Pa, and the treatment time is typically 0.5 to 30 minutes. The oxygen-containing gas can contain one or more gases selected from, for example, hydrogen, argon, and methane tetrafluoride, in addition to oxygen. The substrate surface-treated by the plasma treatment can be washed with water for example.

It is presumed that the affinity between the metal film surface and the plating solution can be enhanced by performing the plasma treatment with the oxygen-containing gas in the step (4) for the following reasons.

Examples of the treatment for removing organic substances adhering to the surface of the metal film before the plating treatment include: the wet treatment with an aqueous solution of potassium permanganate or an aqueous solution of sulfuric acid; plasma treatment with oxygen-containing gas; and dry treatment such as treatment with ozone and ultraviolet rays. The compound (C)-containing film is a hydrophobic film, and compound (C) is considered to be hydrophobic, and therefore aqueous solutions such as an aqueous solution of potassium permanganate and an aqueous solution of sulfuric acid do not sufficiently mix with the compound (C)-containing film and compound (C). As a result, it is presumed that the compound (C)-containing film was not able to be removed satisfactorily by the wet treatment, failing to enhance the affinity between the metal film surface and the plating solution.

In addition, in the case of the treatment with ozone and ultraviolet rays among the dry treatments, ozone reacts mainly in the deep portion of the film, and therefore it is presumed that ozone failed to react satisfactorily with the compound (C)-containing thin film on the surface of the metal film.

Whereas, the plasma treatment with the oxygen-containing gas mainly reacts on the film surface, and therefore reacts efficiently with the compound (C)-containing thin film on the metal film surface, allowing satisfactorily removing the compound (C)-containing film. As a result, it is presumed that the affinity between the metal film surface and the plating solution was able to be improved.

The above description is speculative and does not limit the present invention.

### [Step (5)]

In the step (5), after the plasma treatment, the resist pattern film is used as a mold to form a plated formed product by the plating treatment in the opening (for example, in the case of the positive type, the portion removed by development) defined by the resist pattern film.

Examples of the plated formed product include a bump and wiring. The plated formed product consists of, for example, a conductor such as copper, gold, and nickel. The thickness of the plated formed product varies depending on the application thereof. For example, in the case of a bump, the thickness is typically 5 to 100 μm, preferably 10 to 80 μm, and more preferably 20 to 60 μm. In the case of a wiring, the thickness is typically 1 to 30 μm, preferably 3 to 20 μm, and more preferably 5 to 15 μm.

Examples of the plating treatment include a plating solution treatment using a plating solution. Examples of the plating solution include copper plating solution, gold plating solution, nickel plating solution, and solder plating solution. Specific examples thereof include a copper plating solution including copper sulfate or copper pyrophosphate, a gold plating solution including gold potassium cyanide, and a nickel plating solution including nickel sulfate or nickel carbonate. Of these, a copper plating solution is preferable. The plating solution typically contains a hydrophilic solvent such as water and alcohol.

Specific examples of the plating treatment include the wet plating treatment such as electrolytic plating treatment, electroless plating treatment, and melting plating treatment. When forming a bump and wiring in processing at the wafer level, the electrolytic plating treatment is typically performed.

In the case of the electrolytic plating treatment, the plating film formed on the inner wall of the resist pattern film by the sputtering method or the electroless plating treatment can be used as the seed layer, and the above metal film on the substrate can also be used as the seed layer. Furthermore, a barrier layer may be formed before the seed layer is formed, and the seed layer can be used as the barrier layer.

The conditions of the electrolytic plating treatment can be appropriately selected depending on, for example, the type of plating solution. In the case of a copper plating solution, the temperature is typically 10 to 90° C., preferably 20 to 70° C., and the current density is typically 0.3 to 30 A/dm², preferably 0.5 to 20 A/dm². In the case of a nickel plating solution, the temperature is typically 20 to 90° C., preferably 40 to 70° C., and the current density is typically 0.3 to 30 A/dm², preferably 0.5 to 20 A/dm².

Different plating treatments can be sequentially performed as the plating treatment. For example, a copper-pillar bump can be formed by first performing a copper plating treatment, then performing a nickel plating treatment, and then performing a melting solder plating treatment.

### [Other Steps]

The method for producing a plated formed product according to the present invention can have a step of performing a desmear treatment after the step (4) and before the step (5). Examples of the desmear treatment include known desmear treatments other than plasma treatment with the oxygen-containing gas. Examples of the desmear treatment include: the wet treatment with acidic aqueous solutions such as an aqueous solution of potassium permanganate and aqueous solution of sulfuric acid and with alkaline aqueous solutions such as an aqueous solution of sodium hydroxide and an aqueous solution of tetramethylammonium hydroxide; that is, washing with these aqueous solutions; and the dry treatment with ozone and ultraviolet rays. Compound (C) has a high affinity for the surface of the metal film, and a very small amount of compound (C) can remain on the surface of the metal film depending on the composition of the positive type composition, the content of each component, and the conditions of the plasma treatment. In such a case, performing the present step can improve the effect of the present invention, such as improving the adhesion strength of a plated formed product and suppressing contamination of the plating solution. As long as the amount of compound (C) remaining after the plasma treatment is very small, it is considered that the above problem that the above aqueous solutions do not sufficiently mix with compound (C) does not manifest.

The method for producing a plated formed product of the present invention can further include a step of removing the above resist pattern film after the step (5). Specifically, this step is a step of peeling and removing the remaining resist pattern film, and examples thereof include a method of immersing a substrate having a resist pattern film and a plated formed product in a peeling solution. The temperature and immersion time of the peeling solution is typically 1 to 10 minutes at 20 to 80° C.

Examples of the peeling solution include a peeling solution containing at least one selected from tetramethylammonium hydroxide, dimethyl sulfoxide, and N,N-dimethylformamide.

The method for producing a plated formed product of the present invention can further include a step of removing, for example, by a wet etching method the metal film in the region other than the region with the plated formed product formed.

### EXAMPLES

Hereinafter, the present invention will be described in more detail based on examples, but the present invention is not limited to these examples.

### <Weight Average Molecular Weight of Polymer (Mw)>

The weight average molecular weight (Mw) of the polymer was measured by the gel permeation chromatography method under the following conditions.
GPC apparatus: product name “HLC-8220-GPC” manufactured by Tosoh Corporation
Column: TSK-M and TSK2500 columns manufactured by Tosoh Corporation were connected in series
Solvent: tetrahydrofuran
Temperature: 40° C.
Detection method: refractive index method
Standard substance: polystyrene

### Synthesis Examples 1 and 2

Polymers (A-1) and (A-2) having the structural units and the content ratios thereof shown in Table 1 were produced by radical polymerization using 2,2′-azobis(methylisobutyrate) as a radical polymerization initiator. Details of the structural units shown in Table 1 are described in the following formulas (a1-1) to (a1-4), (a2-1) to (a2-2), and (a3-1) to (a3-2). The unit of the numerical values in columns a1-1 to a3-2 in Table 1 is mol %. The content ratio of each structural unit was measured by 1H-NMR.

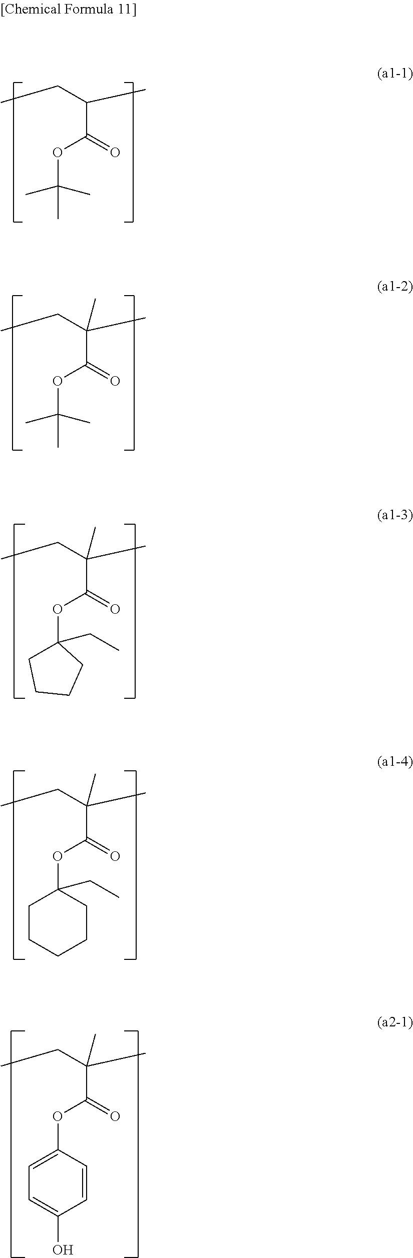

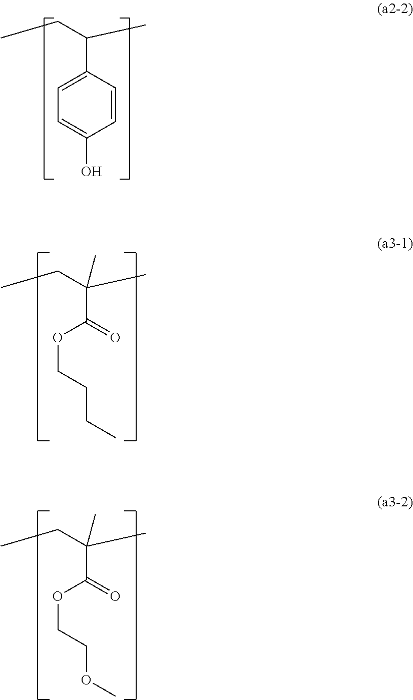

TABLE 1

| Poly- | | | | | | | | | |
|---|---|---|---|---|---|---|---|---|---|
| mer | a1-1 | a1-2 | a1-3 | a1-4 | a2-1 | a2-2 | a3-1 | a3-2 | Mw |
| A-1 | 10 | 10 | | 20 | 45 | | | 15 | 40120 |
| A-2 | 25 | | 10 | | 25 | 20 | 20 | | 21500 |

### <Production of Photosensitive Resin Composition>

### [Production Examples 1 to 11] Production of Photosensitive Resin Composition

The photosensitive resin compositions in Production Examples 1 to 11 were produced by uniformly mixing each component of the type and amount shown in Table 2 below. Details of each component other than the polymer component are as follows. The unit of the numerical value in Table 2 is part by mass.

B-1: compound represented by the following formula (B-1)

B-2: compound represented by the following formula (B-2)

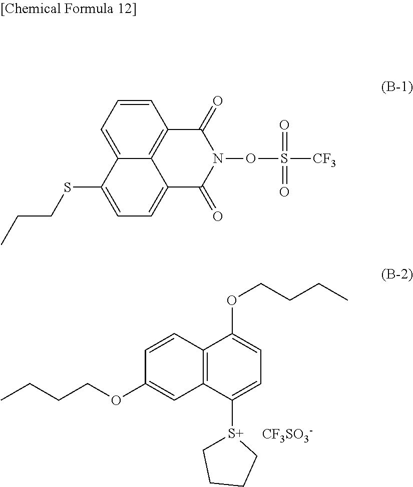

C-1: dimethyl trisulfide

C-2: 4,4′-thiobisbenzenethiol

C-3: compound represented by the following formula (C-3)

C-4: compound represented by the following formula (C-4)

C-5: compound represented by the following formula (C-5)

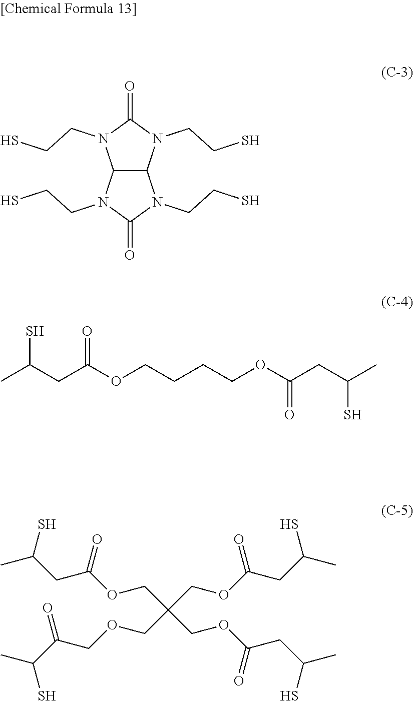

D-1: compound represented by the following formula (D-1)

D-2: compound represented by the following formula (D-2).

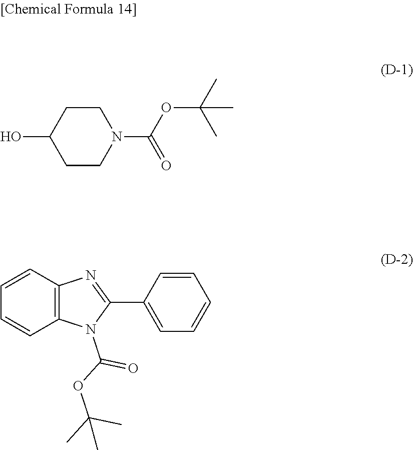 [SMILES: CC(C)(C)OC(=O)N1CCC(O)CC1 ; CC(C)(C)OC(=O)n1c(-c2ccccc2)nc2ccccc21]

E-1: fluorine-based surfactant

(product name “NBX-15”, manufactured by Neos Corporation)

F-1: γ-butyrolactone

F-2: cyclohexanone

F-3: propylene glycol monomethyl ether acetate

TABLE 2

| | Production | Production | Production | Production | Production | Production | Production | Production | Production | Production | Production |
|---|---|---|---|---|---|---|---|---|---|---|---|
| | Example | Example | Example | Example | Example | Example | Example | Example | Example | Example | Example |
| | 1 | 2 | 3 | 4 | 5 | 6 | 7 | 8 | 9 | 10 | 11 |
| A-1 | 100 | | 100 | 100 | 100 | 100 | 100 | 100 | 100 | 100 | 100 |
| A-2 | | 100 | | | | | | | | | |
| B-1 | 1 | 1 | 1 | | 1 | | 1 | 1 | 1 | 1 | 1 |
| B-2 | | | | 3 | | 3 | | | | | |
| C-1 | 1 | | | | | | | | | | |
| C-2 | | 0.2 | | | | | | | | | |
| C-3 | | | 0.5 | | | | | 0.15 | 0.3 | 2 | 2.5 |
| C-4 | | | | 0.5 | | 0.15 | | | | | |
| C-5 | | | | | 0.2 | | 0.15 | | | | |
| D-1 | 2 | 2 | 2 | 2 | | 2 | | 2 | 2 | 2 | 2 |
| D-2 | | | | | 2 | | 2 | | | | |
| E-1 | 0.1 | 0.01 | 0.01 | 0.1 | 0.05 | 0.1 | 0.05 | 0.01 | 0.01 | 0.01 | 0.01 |
| F-1 | | 10 | | | | | | | | | |
| F-2 | | | 5 | | 2 | | 2 | 5 | 5 | 5 | 5 |
| F-3 | 160 | 160 | 160 | 160 | 160 | 160 | 160 | 160 | 160 | 160 | 160 |

### <Production of Plated Formed Product>

### Examples 1A to 11A, Example 1D, Comparative Examples 1B to 5B, and Comparative Examples 1C to 11C

Using a spin coater, the photosensitive resin compositions in Production Examples 1 to 11 were applied onto the copper sputtered film of a silicon wafer substrate provided with a copper sputtered film, and heated at 120° C. for 60 seconds to form a coating having a film thickness of 6 μm. The above coating was exposed using a stepper (model “NSR-i10D” manufactured by Nikon Corporation) via a pattern mask. The exposed coating was heated at 90° C. for 60 seconds and then immersed in a 2.38% by mass of tetramethylammonium hydroxide aqueous solution for 180 seconds to perform development. Thereafter, washing with running water and then blowing with nitrogen provided formation of the resist pattern films (line width: 2 μm, line width/space width=1/1) on the copper sputtered film of the substrate. The substrate with this resist pattern film formed is referred to as “patterning substrate”.

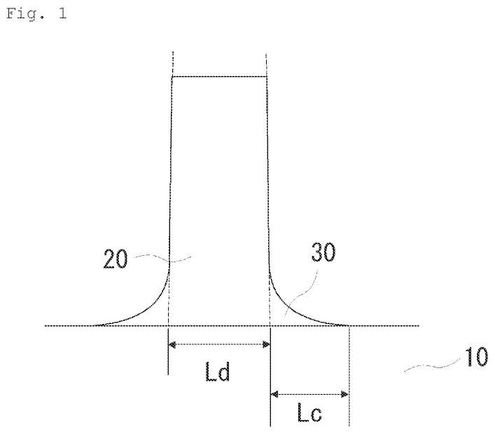

Regarding the obtained patterning substrate, the condition of the interface between the resist pattern film and the copper sputtered film was observed. The obtained cross section of 1L (line) 1S (space) having a line width of 2 μm was observed by using a scanning electron microscope, and the width Lc and width Ld shown in FIG. 1 were measured and evaluated according to the following criteria. In FIG. 1, the hem of the pattern is exaggerated.
Lc/Ld<0.005: “footing” is “⊙”.
0.005≤Lc/Ld<0.05: “footing” is “◯”.
0.05≤Lc/Ld<0.1: “footing” is “Δ”.
0.1≤Lc/Ld: “footing” is “x”.

The evaluation results are shown in Table 3.

Using the resist pattern film as a mold, the electrolytic plating treatment was performed to produce a plated formed product. The following pretreatments A to D were performed as a pretreatment for the electrolytic plating treatment. The pretreated patterning substrate was immersed in 1 L of a copper plating solution (product name “MICROFAB SC-40”, manufactured by MacDermid Performance Solutions Japan K.K.), and the electroplating treatment was performed at a plating bath temperature of 25° C. and a current density of 8.5 A/dm² for 2 minutes and 10 seconds to produce a plated formed product.

Pretreatment A: treatment with oxygen plasma (output of 100 W, oxygen flow rate of 100 ml, treatment time of 60 seconds) was performed, and then washing treatment with water was performed.

Pretreatment B: immersing in 10% by mass of sulfuric acid aqueous solution at 23° C. for 60 seconds, and then washing treatment with water was performed.

Pretreatment C: no pretreatment

Pretreatment D: treatment with oxygen plasma (output of 100 W, oxygen flow rate of 100 ml, treatment time of 60 seconds) was performed, immersing in 1% by mass of sulfuric acid aqueous solution at 23° C. for 120 seconds, and then washing treatment with water was performed.

The condition of the produced plated formed product was observed with an electron microscope and evaluated according to the following evaluation criteria. The evaluation results are shown in Table 3 below.

AA: there was no peeling, and a rectangular plated formed product was formed.

A: the shape of the plated formed product at the metal surface interface was thin; however, there was no peeling.

B: a rectangular plated formed product was formed; however, peeling occurred in less than 50% of the area.

BB: 50% or more of the plated formed product was peeled off from the substrate.

Tab1e 3

| Production of plated | Photosensitive resin | | | Condition of |
|---|---|---|---|---|
| formed product | composition | Pretreatment | Footing | plated formed product |
| Example 1A | Production Example 1 | A | ◯ | AA |
| Comparative Example 1B | Production Example 1 | B | ◯ | BB |
| Comparative Example 1C | Production Example 1 | C | ◯ | BB |
| Example 1D | Production Example 1 | D | ◯ | AA |
| Example 2A | Production Example 2 | A | Δ | AA |
| Comparative Example 2B | Production Example 2 | B | Δ | BB |
| Comparative Example 2C | Production Example 2 | C | Δ | BB |
| Example 3A | Production Example 3 | A | ⊙ | AA |
| Comparative Example 3B | Production Example 3 | B | ⊙ | BB |
| Comparative Example 3C | Production Example 3 | C | ⊙ | BB |
| Example 4A | Production Example 4 | A | ◯ | AA |
| Comparative Example 4B | Production Example 4 | B | ◯ | BB |
| Comparative Example 4C | Production Example 4 | C | ◯ | BB |
| Example 5A | Production Example 5 | A | ◯ | AA |
| Comparative Example 5B | Production Example 5 | B | ◯ | BB |
| Comparative Example 5C | Production Example 5 | C | ◯ | BB |
| Example 6A | Production Example 6 | A | Δ | A |
| Comparative Example 6C | Production Example 6 | C | Δ | BB |
| Example 7A | Production Example 7 | A | Δ | A |
| Comparative Example 7C | Production Example 7 | C | Δ | BB |
| Example 8A | Production Example 8 | A | Δ | A |
| Comparative Example 8C | Production Example 8 | C | Δ | BB |
| Example 9A | Production Example 9 | A | ⊙ | AA |
| Comparative Example 9C | Production Example 9 | C | ⊙ | BB |
| Example 10A | Production Example 10 | A | ⊙ | AA |
| Comparative Example 10C | Production Examp1e 10 | C | ⊙ | BB |
| Example 11A | Production Examp1e 11 | A | ◯ | B |
| Comparative Example 11C | Production Examp1e 11 | C | ◯ | BB |

### [Plating Solution Contamination]

Regarding Example 1A and Example 1D, two copper plating solutions were prepared, and the plated formed product was formed repeatedly on 50 pieces of patterning substrates under the same conditions as in Example 1A and Example 1D according to <Production of plated formed product>.

Regarding the two copper plating solutions, the contamination properties of the plating solutions were evaluated according to the following criteria, before plating and after the 50th plating. The conductivity of the plating solution was measured with a portable conductivity meter ES-71 produced by HORIBA, Ltd.
Method of Example 1D: the change in conductivity of the plating solution before and after plating is less than 10%

(no plating solution contamination).
Method of Example 1A: the change in conductivity of the plating solution before and after plating is 10% or more (plating solution contamination).

### REFERENCE SIGNS LIST

10 Substrate with metal film
20 Resist pattern film
30 Footing

1: A method for producing a plated formed product, the method comprising:
a step (1) of forming on a substrate of the substrate having a metal film a resin film of a photosensitive resin composition containing a sulfur-containing compound having at least one selected from a mercapto group, a sulfide bond, and a polysulfide bond;
a step (2) of exposing the resin film;
a step (3) of developing the exposed resin film to form a resist pattern film;
a step (4) of performing plasma treatment of a substrate having the resist pattern film on the metal film with oxygen-containing gas; and
a step (5) of performing, after the plasma treatment, plating treatment with the resist pattern film as a mold.

2: The method for producing a plated formed product according to claim 1, wherein the photosensitive resin composition further contains polymer (A) having an acid dissociative group and photoacid generator (B).

3: The method for producing a plated formed product according to claim 2, wherein a content of the sulfur-containing compound is 0.2 to 2.0 parts by mass, with respect to 100 parts by mass of a polymer component including polymer (A) having an acid dissociative group included in the photosensitive resin composition.

4: The method for producing a plated formed product according to claim 1, wherein the resist pattern film has a thickness of 1 to 100 μm.

5: The method for producing a plated formed product according to claim 1, wherein the metal film is a copper film.

6: The method for producing a plated formed product according to claim 1, wherein the plating treatment is a copper plating treatment.

7: The method for producing a plated formed product according to claim 1, comprising a step of washing a substrate having a plasma-treated resist pattern film on a metal film with an acid before the step (5).

8: The method for producing a plated formed product according to claim 1, comprising a step of washing a substrate having a plasma-treated resist pattern film on a metal film with an aqueous solution of potassium permanganate or an aqueous solution of sulfuric acid before the step (5).
